(19) United States
(12) Patent Application Publication
(10) Pub. No.: US 2021/0074721 A1
(43) Pub. Date: Mar. 11, 2021

(54) SEMICONDUCTOR STORAGE DEVICE AND MANUFACTURING METHOD OF THE SAME

(71) Applicant: Kioxia Corporation, Minato-ku (JP)

(72) Inventor: Hironobu HAMANAKA, Yokkaichi (JP)

(73) Assignee: Kioxia Corporation, Minato-ku (JP)

(21) Appl. No.: 16/897,836

(22) Filed: Jun. 10, 2020

(30) Foreign Application Priority Data
Sep. 10, 2019 (JP) 2019-164761

(51) Int. Cl. H01L 27/11582; H01L 21/311; H01L 21/28; H01L 21/02

(52) U.S. Cl. CPC H01L 27/11582; H01L 21/02636; H01L 29/40117; H01L 21/31116

(57) ABSTRACT

A disclosed semiconductor storage device includes a stacked-layer structure in which insulating layers and electrically conductive layers are alternately stacked one on another above a base body; a semiconductor layer buried in a bottom portion of a hole that penetrates the stacked-layer structure; a memory layer formed on an inner side surface of the hole having the semiconductor layer buried at the bottom portion thereof; and a channel layer formed on the memory layer in the hole having the semiconductor layer buried at the bottom portion thereof. An upper surface of the semiconductor layer is located within a widened region formed in a part of the hole.

### CROSS-REFERENCE TO RELATED APPLICATIONS

This application is based upon and claims the benefit of priority from Japanese Patent Application No. 2019-164761, filed on Sep. 10, 2019; the entire contents of which are incorporated herein by reference.

### FIELD

Embodiments of the present disclosure relate to a semiconductor storage device and a manufacturing method of the same.

### BACKGROUND

In the past, there have been known semiconductor storage devices including three dimensionally arranged memory cells. These memory cells may be configured by piercing memory holes in a stacked body in which electrically conductive layers and insulating layers are alternately stacked one on the other, and by forming semiconductor pillars and gate insulating films that surround corresponding lateral surfaces of the semiconductor pillars within the memory holes.

### BRIEF DESCRIPTION OF THE DRAWINGS

FIG. 1 is a manufacturing flowchart of a semiconductor storage device according to a first embodiment;

FIG. 2A is an explanatory view for explaining, in order of processing, a manufacturing method of the semiconductor storage device according to the first embodiment;

FIG. 2B is an explanatory view for explaining, in order of processing, the manufacturing method of the semiconductor storage device according to the first embodiment, following FIG. 2A;

FIG. 2C is an explanatory view for explaining, in order of processing, the manufacturing method of the semiconductor storage device according to the first embodiment, following FIG. 2B;

FIG. 3A is an explanatory view for explaining, in order of processing, the manufacturing method of the semiconductor storage device according to the first embodiment, following FIG. 2C;

FIG. 3B is an explanatory view for explaining, in order of processing, the manufacturing method of the semiconductor storage device according to the first embodiment, following FIG. 3A;

FIG. 4 is a cross-sectional view of the semiconductor storage device, in progress, according to the first embodiment;

FIG. 5 is a cross-sectional view of the semiconductor storage device according to the first embodiment;

FIG. 6 is a manufacturing flowchart of a semiconductor storage device according to a second embodiment;

FIG. 7A is an explanatory view for explaining, in order of processing, a manufacturing method of the semiconductor storage device of according to the second embodiment;

FIG. 7B is an explanatory view for explaining, in order of processing, the manufacturing method according to the second embodiment, following FIG. 7A;

FIG. 7C is an explanatory view for explaining, in order of processing, the manufacturing method according to the second embodiment, following FIG. 7B;

FIG. 8A is an explanatory view for explaining, in order of processing, the manufacturing method according to the second embodiment, following FIG. 7C;

FIG. 8B is an explanatory view for explaining, in order of processing, the manufacturing method according to the second embodiment, following FIG. 8A; and

FIG. 9 is a cross-sectional view of the semiconductor storage device, in progress, according to the second embodiment.

### DETAILED DESCRIPTION

A semiconductor storage device according to embodiments is provided with a stacked-layer structure in which insulating layers and electrically conductive layers are alternately stacked one on another above a base body; a semiconductor layer buried in a bottom portion of a hole that penetrates the stacked-layer structure; a memory layer formed on an inner side surface of the hole having the semiconductor layer buried at the bottom portion thereof; and a channel layer formed on the memory layer in the hole having the semiconductor layer buried at the bottom portion thereof. An upper surface of the semiconductor layer is located within a widened region formed in a part of the hole.

Non-limiting, exemplary embodiments of the present disclosure will now be described with reference to the accompanying drawings. In the drawings, the same or corresponding reference marks are given to the same or corresponding members or components, and redundant explanations will be omitted. It is to be noted that the drawings are illustrative of the disclosure, and there is no intention to indicate scale or relative proportions among the members or components, or between thicknesses of various layers. Therefore, the specific thickness or size should be determined by a person having ordinary skill in the art in view of the following non-limiting embodiments.

### First Embodiment

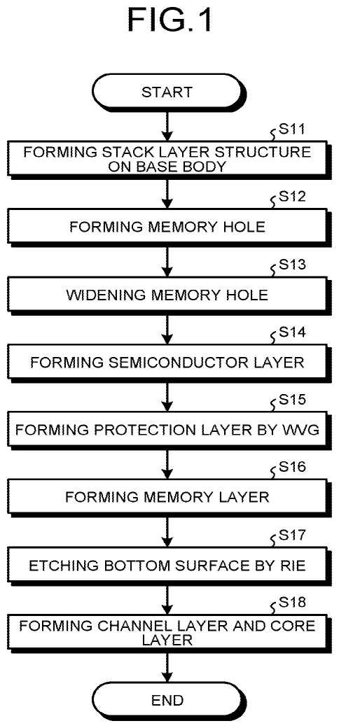

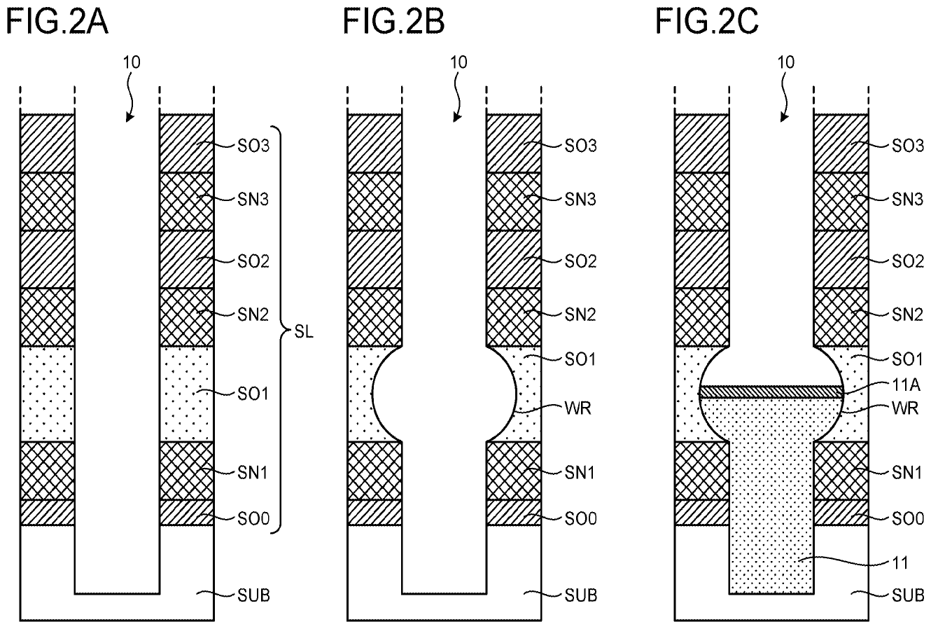

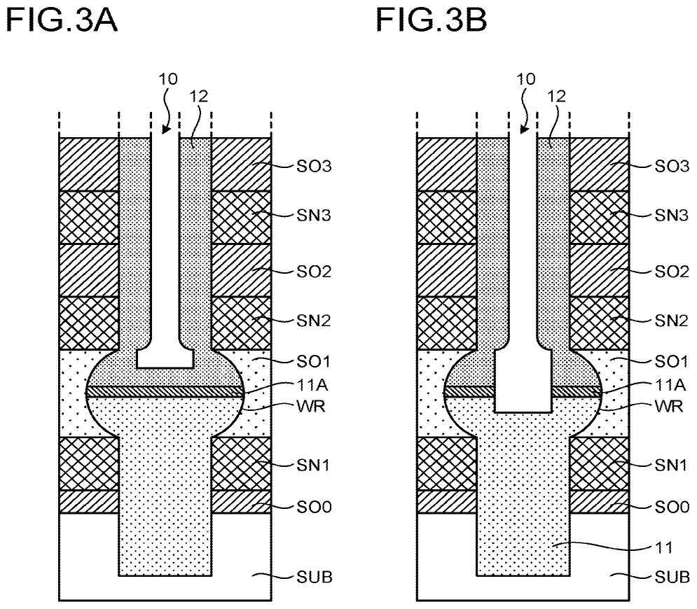

Referring to FIG. 1 through FIG. 5, a manufacturing method of a semiconductor storage device according to a first embodiment will be described. FIG. 1 is a manufacturing flowchart of the semiconductor storage device according to the first embodiment. FIGS. 2A through 3B are explanatory views for explaining, in order of processing, the manufacturing method according to the first embodiment. First, insulating layers SO0, SO1, SO2, SO3, . . . , which are formed of, for example, silicon oxide, and sacrificial layers SN1, SN2, . . . , which are formed of, for example, silicon nitride, are alternately stacked one on the other on a substrate SUB that is exemplified as a base body in this embodiment. With this, a stacked-layer structure SL is obtained (Step S11). The substrate SUB includes a semiconductor material. For example, a single crystalline silicon wafer may be used as the substrate SUB. Around the stacked-layer structure SL, an interlayer dielectric may be formed.

In the stacked-layer structure SL, the insulating layer SO1 between the sacrificial layer SN1 and the sacrificial layer SN2 is formed of silicon oxide that has a higher wet or dry etching rate than silicon oxide that constitutes the insulating layers SO2, SO3, . . . , which are formed on the upper layer side of the insulating layer SO1. Here, the sacrificial layer SN1 is the lowest layer or the nearest neighbor sacrificial layer to the substrate SUB among the sacrificial layers SN1, SN2, . . . within the stacked-layer structure SL. The sacrificial layer SN2 is the second lowest layer or the sacrificial layer next to the sacrificial layer SN1 on the upper layer side of the sacrificial layer SN1. Additionally, the insulating layer SO1 formed of silicon oxide having a higher etching rate is thicker than the other insulating layers SO2, SO3, . . . , on the upper layer side of the insulating layer SO1.

Next, a photoresist pattern is formed on an upper surface of the stacked-layer structure SL. The photoresist pattern has an opening in a position where a semiconductor pillar is to be formed. Then, the stacked-layer structure SL is etched by an anisotropic etching method such as a reactive ion etching (RIE) method, using the photoresist pattern as a mask. With this, a memory hole 10 that penetrates the stacked-layer structure SL is formed as illustrated in FIG. 2A (Step S12).

Subsequently, a wet etching is performed using a diluted hydrofluoric acid (DHF) solution, and thus a part of the memory hole 10 is enlarged in diameter or in lateral directions. With this, a widened region WR is formed as illustrated in FIG. 2B (Step S13).

Specifically, because the insulating layer SO1 is formed of silicon oxide that has a higher wet etching rate than silicon oxide that constitutes the other insulating layers SO2, SO3, . . . , as described above, the insulating layer SO1 is etched to a greater extent than the insulating layers SO2, 503, . . . , as illustrated in FIG. 2B. Namely, the insulating layer SO1 is etched further in lateral directions, and thus the widened region WR is formed in the insulating layer SO1.

Incidentally, in order to form the insulating layer SO1 with silicon oxide that has a higher wet etching rate than silicon oxide that constitutes the insulating layers SO2, 503, . . . , the insulating layer SO1 may be deposited under different deposition conditions from those for the other insulating layers SO2, SO3, . . . . For example, the insulating layer SO1 may be deposited at a lower temperature by a plasma chemical vapor deposition (CVD). The silicon oxide layer deposited at a lower temperature may contain relatively larger amount of impurities. Alternatively, such silicon oxide layer may contain a larger number of Si—OH bonds or Si—H bonds and a smaller number of Si—O bonds. Namely, the silicon oxide that constitutes the insulating layer SO1 may be oxygen-depleted silicon oxide, or silicon oxide deviated from the stoichiometric composition. Therefore, the insulating layer SO1 becomes more susceptible to wet etching.

Next, a single crystalline semiconductor layer (for example, a single crystalline silicon layer) 11 is grown in a bottom portion of the memory hole 10, as illustrated in FIG. 2C, by a selective epitaxial growth method (Step S14). Here, because the insulating layer SO1 has a greater layer thickness than the other insulating layers SO2, 503, . . . , the bottom portion of the memory hole 10 can be buried with the semiconductor layer 11 so that an upper surface of the semiconductor layer 11 is located easily within the widened region WR.

Then, the upper surface of the semiconductor layer 11 is exposed to an oxidizing atmosphere produced by a water vapor generator (WVG), and thus oxidized. With this, a silicon oxide film is formed on the semiconductor layer 11. This silicon oxide film serves as a protection film for the semiconductor layer 11, and is referred to as a protection film 11A hereinafter (Step S15, see FIG. 2C).

Next, as illustrated in FIG. 3A, a memory layer 12 is formed on an inner side surface and bottom surface of the memory hole 10. For example, the memory layer 12 includes a silicon oxide layer, a silicon nitride layer, and another silicon oxide layer, which are stacked in this order.

Specifically, the memory layer 12 includes a block insulating layer formed of silicon oxide or the like on the inner side surface and bottom surface of the memory hole 10; a charge storage layer formed of silicon nitride or the like on the block insulating layer; and a tunnel insulating layer formed of silicon oxide or the like on the charge storage layer.

Subsequently, a part of the memory layer 12, the part being exposed as the bottom surface of the memory hole 10, is etched by the RIE method (Step S17). In this etching, the protection film 11A and at least an upper part of the semiconductor layer 11 are also etched. As a result, a larger area of the semiconductor layer 11 becomes exposed, as illustrated in FIG. 3B. Incidentally, the upper part of the semiconductor layer 11 may be etched further to produce a recessed portion therein (see FIG. 3B).

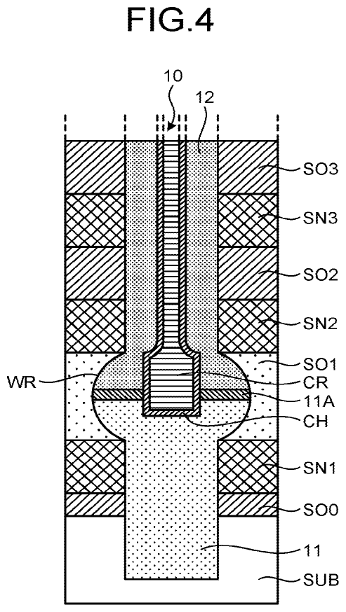

Next, a channel layer CH and a core layer CR, which serve as a semiconductor pillar (column), are formed (Step S18). FIG. 4 illustrates a cross-sectional view of the semiconductor storage device that has been processed up to this stage. The channel layer CH is formed of, for example, amorphous silicon, poly silicon, or the like. The core layer CR is formed of, for example, silicon oxide.

With the above configuration, as illustrated in FIG. 4, a contact area between the semiconductor layer 11 and the channel layer CH can be increased, which allows a contact resistance between the semiconductor layer 11 and the channel layer CH to be reduced.

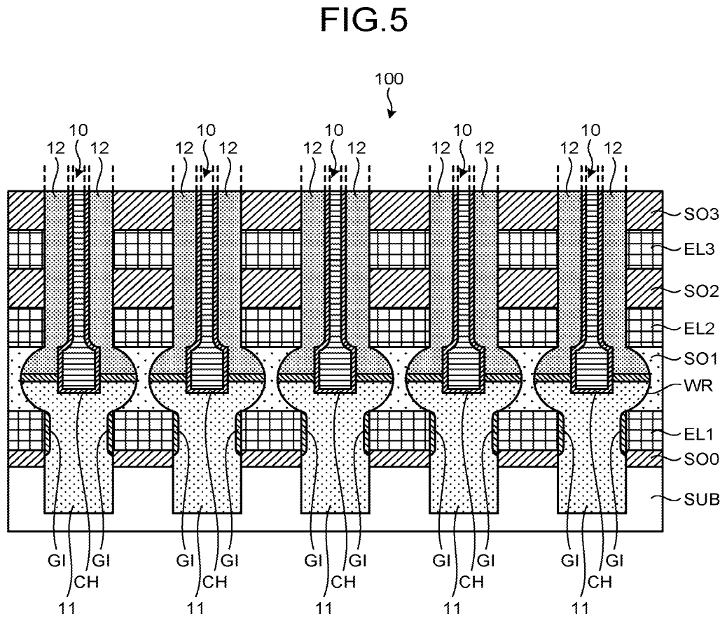

Next, the sacrificial layers SN1, SN2, SN3, . . . are replaced with an electrically conductive material such as Tungsten (W), using the pillar as a supporting member, and thus are turned into electrically conductive layers EL1, EL2, EL3, . . . , respectively. FIG. 5 is a cross-sectional view illustrating the semiconductor storage device according to the first embodiment. The electrically conductive layers EL1, EL2, EL3, . . . , which have been formed by being replaced with the sacrificial layers SN1, SN2, SN3, . . . , are used as word lines, a selective gate line, or the like. Here, before the electrically conductive layers EL1, EL2, EL3, . . . are formed, gate-insulating films GI are formed on corresponding outer side surfaces of the semiconductor layers 11. In such configuration, intersecting portions of the semiconductor pillars and the electrically conductive layer EL1 function as selective transistors, and intersecting portions of the semiconductor pillars and the electrically conductive layers EL2, EL3, . . . function as memory cells. With this, a semiconductor storage device 100 in which plural memory cells are three-dimensionally arranged is obtained, as illustrated in FIG. 5.

In FIG. 5, although only a lower portion of the semiconductor storage device 100 is illustrated, several tens to one hundred or more of the insulating layers and electrically conductive layers may be alternately stacked one on the other in the semiconductor storage device 100. By increasing the number of the stacked layers, storage capacity can be increased, which allows costs per bit to be reduced, without relying on highly precise patterning technology.

As described above, according to the first embodiment, when the semiconductor layer 11, the protection film 11A, and the memory layer 12 are formed in the bottom portion of the memory hole 10 having the widened region WR, the upper surface of the semiconductor layer 11, the protection film 11A, and the memory layer 12 are located in the widened region WR. With this, when the bottom surface of the memory hole 10 is etched, a larger area of the semiconductor layer 11 can be exposed. Therefore, when the channel layer CH is formed on the semiconductor layer 11, the channel layer CH can be in contact at a larger area with the semiconductor layer 11, which allows the contact resistance therebetween to be reduced.

### Second Embodiment

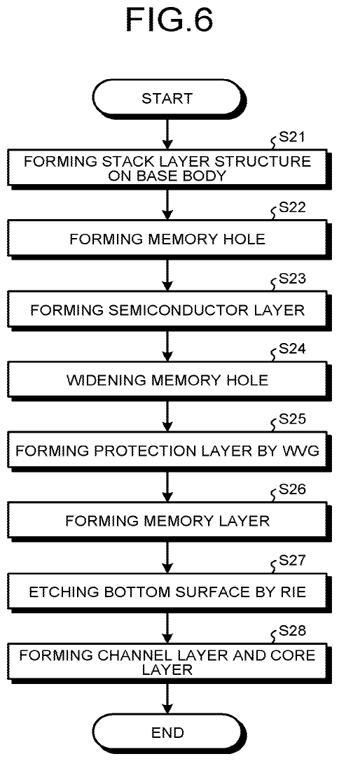

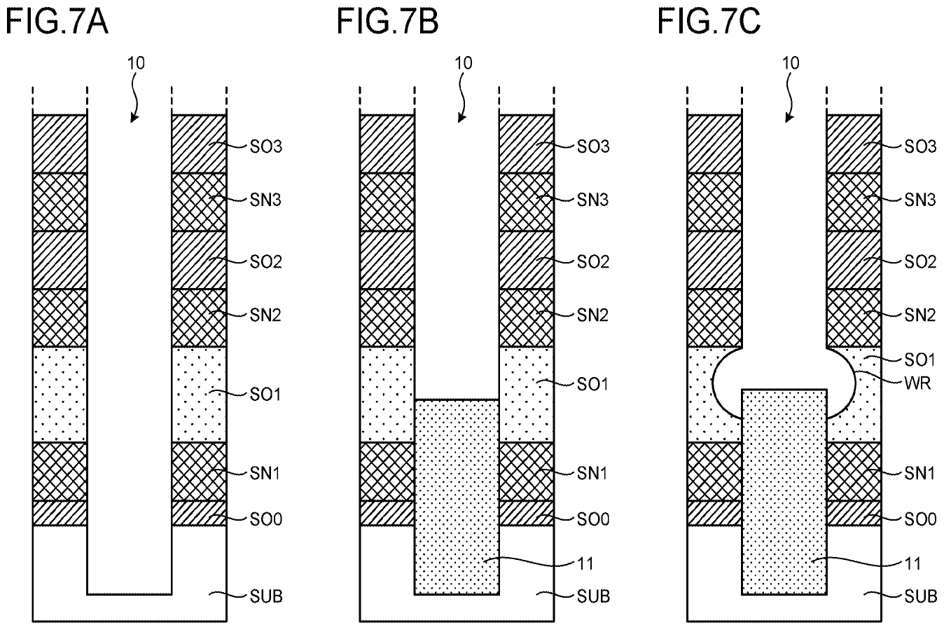

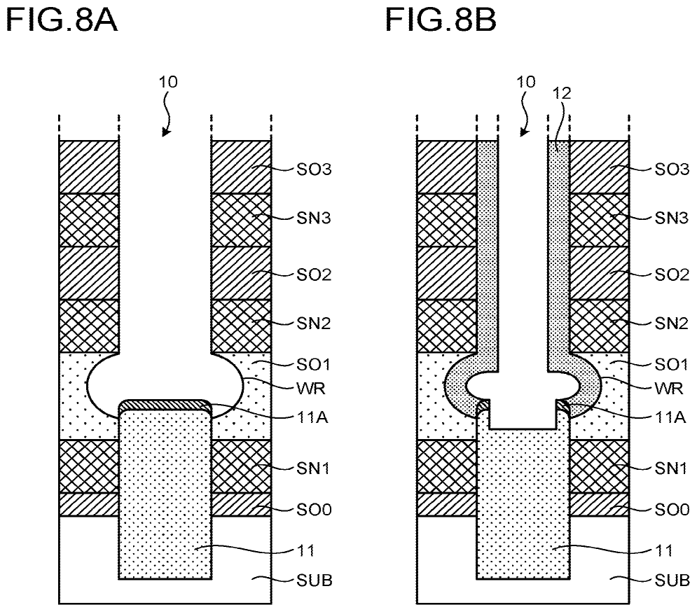

FIG. 6 is a manufacturing flowchart of a semiconductor storage device according to a second embodiment; and FIG. 7A through FIG. 8B are explanatory views for explaining, in order of processing, a manufacturing method of the semiconductor storage device according to the second embodiment. Referring to FIG. 6, insulating layers SO0, SO1, SO2, SO3, . . . , which are formed of, for example, silicon oxide, and sacrificial layers SN1, SN2, . . . , which are formed of, for example, silicon nitride, are alternately stacked one on the other above a substrate SUB, and thus, an stacked-layer structure SL is obtained (Step S21). Around the stacked-layer structure SL, an interlayer dielectric (not illustrated) may be formed.

Even in the second embodiment, the insulating layer SO1 between the sacrificial layer SN1 and the sacrificial layer SN2 is formed of silicon oxide that has a higher wet etching rate or dry etching rate than silicon oxide that constitutes the other insulating layers SO2, SO3, . . . in the stacked-layer structure SL. Here the sacrificial layer SN1 is the lowest layer among the sacrificial layers SN1, SN2, SN3, . . . within the stacked-layer structure SL, and the sacrificial layer SN2 is the second lowest layer to the lowest layer. Additionally, the insulating layer SO1 formed of the silicon oxide having a higher etching rate is thicker than the other insulating layers SO2, SO3, . . . on the upper layer side.

Next, a photoresist pattern, which has an opening in a position where a semiconductor pillar is to be formed, is formed on an upper surface of the stacked-layer structure SL. The stacked-layer structure SL is etched by an anisotropic etching method such as a reactive ion etching (RIE) method, using the photoresist pattern as a mask. With this, a memory hole 10 is formed which penetrates the stacked-layer structure SL as illustrated in FIG. 2A (Step S22).

Next, a single crystalline semiconductor layer (for example, a single crystalline silicon layer) 11 is grown in a bottom portion of the memory hole 10, as illustrated in FIG. 7B, by a selective epitaxial growth method. Here, the semiconductor layer 11 is formed so that an upper surface of the semiconductor layer 11 is located within a space defined by the insulating layer SO1 of the memory hole 10 (Step S23). Then, a wet etching is performed using a diluted hydrofluoric acid (DHF) solution. With this, a part of the memory hole 10 is enlarged in diameter or in lateral directions, the part corresponding to the insulating layer SO1, and thus a widened region WR is formed as illustrated in FIG. 7C (Step S24).

Next, as illustrated in FIG. 8A, an upper surface of the semiconductor layer 11 is exposed to an oxidizing atmosphere produced by using a water vapor generator (WVG), and then oxidized. With this, a silicon oxide film is formed on the semiconductor layer 11. This silicon oxide film is a protection film for the semiconductor layer 11, and is referred to as a protection film 11A hereinafter (Step S25).

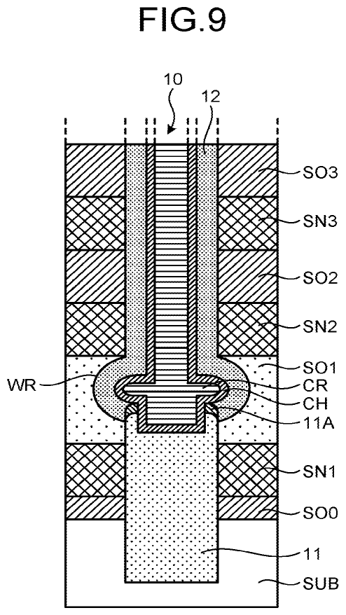

Next, a memory layer 12 is formed on an inner side surface and a bottom surface of the memory hole 10 (Step S26), as with the first embodiment. As illustrated in FIG. 8B, a part of the memory layer 12, the part being exposed on the bottom portion of the memory hole 10, is etched (Step S27). In this etching, the protection layer 11A and at least an upper part of the semiconductor layer 11 is also etched. As a result, a larger area of the semiconductor layer 11 becomes exposed as illustrated in FIG. 8B. Subsequently, a channel layer CH and a core layer CR, which serve as a semiconductor pillar (column), are formed (Step S28). FIG. 9 illustrates the semiconductor storage device that has been processed up to this stage. As illustrated, the channel layer CH can be in contact at a larger area with the semiconductor layer 11, which allows a contact resistance to be reduced.

In FIG. 9, although only a lowest part of the memory hole 10 is illustrated, several tens to one hundred or more of the insulating layers and the sacrificial layers around the memory hole 10 are alternately stacked one on the other.

Next, the sacrificial layers SN1, SN2, SN3, . . . are replaced with an electrically conductive material such as Tungsten (W), using the pillar as a supporting member, and thus are turned into electrically conductive layers EL1, EL2, EL3, . . . , respectively, as with the first embodiment. Before the electrically conductive layers EL1, EL2, EL3, . . . are formed, a gate-insulating film GI is formed on an outer side surface of the semiconductor layers 11. Even in this embodiment, an intersecting portion of the semiconductor pillar and the electrically conductive layer EL1 functions as a selective transistor, and intersecting portions of the semiconductor pillar and the electrically conductive layers EL2, EL3, . . . function as memory cells. In this way, a semiconductor storage device 100 in which plural memory cells are three-dimensionally arranged is obtained (see FIG. 5).

As described above, even in the second embodiment, when the bottom surface of the memory hole 10 is etched, a larger area of the semiconductor layer 11 can be exposed. With this, when the channel layer CH is formed on the semiconductor layer 11, the channel layer CH can be in contact at a larger area with the semiconductor layer 11, which allows the contact resistance therebetween to be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, while the widened region WR is formed by the wet etching method in the above embodiments, the widened region WR may be formed by a dry etching method.

Additionally, although the widened region WR is formed in the insulating layer located between the lowest electrically conductive layer and the second lowest electrically conductive layer of the stacked-layer structure SL in the above embodiments, the widened region WR may be formed, for example but not limited to, in an insulating layer corresponding to a position where the channel layer CH is electrically in contact with the semiconductor layer 11. Even with this, a contact resistance between the channel layer CH and the semiconductor layer 11 can be reduced.

Moreover, while specific examples of manufacturing methods of a semiconductor device have been described, the semiconductor storage device according to embodiments may be manufactured by any manufacturing methods, as long as the widened region of the memory hole can be formed.

What is claimed is:

1. A semiconductor storage device comprising:
a stacked-layer structure in which insulating layers and electrically conductive layers are alternately stacked one on another above a base body;
a semiconductor layer buried in a bottom portion of a hole that penetrates the stacked-layer structure;
a memory layer formed on an inner side surface of the hole having the semiconductor layer buried at the bottom portion thereof; and
a channel layer formed on the memory layer in the hole having the semiconductor layer buried at the bottom portion thereof,
wherein
an upper surface of the semiconductor layer is located within a widened region formed in a part of the hole.

2. The semiconductor storage device according to claim 1, wherein
the widened region is formed in one insulating layer of the insulating layers.

3. The semiconductor storage device according to claim 2, wherein
the one insulating layer is located between a first electrically conductive layer and a second electrically conductive layer among the electrically conductive layers in the stacked-layer structure, the first electrically conductive layer being located nearest to the base body, and the second electrically conductive layer being located second nearest to the base body.

4. The semiconductor storage device according to claim 3, wherein
the first electrically conductive layer functions as a selective gate line of a three-dimensional memory, and
the second electrically conductive layer functions as a word line of the three-dimensional memory.

5. The semiconductor storage device according to claim 2, wherein
the one insulating layer has a higher etching rate than the other insulating layers.

6. The semiconductor storage device according to claim 2, wherein
the one insulating layer is formed thicker than the other insulating layers.

7. The semiconductor storage device according to claim 1, wherein
the memory layer has an opening above the semiconductor layer, the opening allowing the semiconductor layer to be exposed therethrough.

8. The semiconductor storage device according to claim 7, wherein
the channel layer is in contact with the semiconductor layer through the opening.

9. The semiconductor storage device according to claim 8, wherein
the semiconductor layer has a recessed portion that is located below the opening of the memory layer and recessed from the upper surface of the semiconductor layer, and
the channel layer is in contact with the recessed portion of the semiconductor layer.

10. The semiconductor storage device according to claim 1, wherein
the base body includes a semiconductor material, and the semiconductor layer is an epitaxial layer formed on the base body.

11. A manufacturing method of a semiconductor storage device, the method comprising:
alternately stacking insulating layers and sacrificial layers one on another above a base body, such that one insulating layer has a higher etching rate than the other insulating layers, to form a stacked-layer structure;
forming a hole that penetrates the stacked-layer structure;
widening a part of the hole, the part corresponding to the one insulating layer, to form a widened region;
forming a semiconductor layer in a bottom portion of the hole such that an upper surface of the semiconductor layer is located in the widened region;
forming a memory layer within the hole having the widened region, after the semiconductor layer is formed; and
removing at least part of the memory layer above the semiconductor layer, to form an opening of the memory layer.

12. The manufacturing method according to claim 11, wherein
the one insulating layer is located between a first sacrificial layer and a second sacrificial layer among the sacrificial layers in the stacked-layer structure, the first sacrificial layer being located nearest to the base body, and the second sacrificial layer being located second nearest to the base body.

13. The manufacturing method according to claim 11, further comprising forming a channel layer on the memory layer such that the channel layer is in contact with the semiconductor layer through the opening of the memory layer.

14. The manufacturing method according to claim 13, wherein
when at least part of the memory layer above the semiconductor layer is removed, an upper part of the semiconductor layer is removed through the opening, to form a recessed portion therein, and
the channel layer is in contact with the recessed portion of the semiconductor layer.

15. The manufacturing method according to claim 12, further comprising:
removing the first sacrificial layer;
forming an insulating film on an outer side surface of the semiconductor layer, the outer side surface having been exposed by removing the first sacrificial layer; and
forming an electrically conductive layer in a space that has been formed by removing the first sacrificial layer.

16. A manufacturing method of a semiconductor storage device, the method comprising:
alternately stacking insulating layers and sacrificial layers one on another above a base body, such that one insulating layer has a higher etching rate than the other insulating layers, to form a stacked-layer structure;
forming a hole that penetrates the stacked-layer structure;
forming a semiconductor layer in a bottom portion of the hole such that an upper surface of the semiconductor layer is located in a space defined by the one insulating layer;
widening a part of the hole, the part corresponding to the one insulating layer, after the semiconductor layer is formed, to form a widened region;
forming a memory layer within the hole having the widened region; and
removing at least part of the memory layer above the semiconductor layer, to form an opening of the memory layer.

17. The manufacturing method according to claim 16, wherein
the one insulating layer is located between a first sacrificial layer and a second sacrificial layer among the sacrificial layers in the stacked-layer structure, the first sacrificial layer being located nearest to the base body, and the second insulating layer being located second nearest to the base body.

18. The manufacturing method according to claim 16, further comprising forming a channel layer on the memory layer such that the channel layer is in contact with the semiconductor layer through the opening of the memory layer.

19. The manufacturing method according to claim 18, wherein
when at least part of the memory layer above the semiconductor layer is removed, an upper part of the semiconductor layer is removed through the opening, to form a recessed portion therein, and
the channel layer is in contact with the recessed portion of the semiconductor layer.

20. The manufacturing method according to claim 17, further comprising:
removing the first sacrificial layer;
forming an insulating film on an outer side surface of the semiconductor layer, the outer side surface having been exposed by removing the first sacrificial layer; and
forming an electrically conductive layer in a space that has been formed by removing the first sacrificial layer.
